(19) United States
(12) Patent Application Publication
(10) Pub. No.: US 2024/0128140 A1
(43) Pub. Date: Apr. 18, 2024

(54) POWER MODULE PACKAGE HAVING MIRRORED LEADS

(71) Applicant: SEMICONDUCTOR COMPONENTS INDUSTRIES, LLC, Scottsdale, AZ (US)

(72) Inventors: Seungwon IM, Bucheon (KR); Jeonghyuk PARK, Incheon (KR); Keunhyuk LEE, Suzhou (CN); Jerome TEYSSEYRE, Singapore (SG); Paolo BILARDO, Munich (DE)

(73) Assignee: SEMICONDUCTOR COMPONENTS INDUSTRIES, LLC, Scottsdale, AZ (US)

(21) Appl. No.: 18/485,966

(22) Filed: Oct. 12, 2023

Related U.S. Application Data
(60) Provisional application No. 63/379,387, filed on Oct. 13, 2022.

(51) Int. Cl. H01L 23/31; H01L 21/56; H01L 23/367; H01L 23/495

(52) U.S. Cl. CPC H01L 23/3121; H01L 21/56; H01L 23/367; H01L 23/49555

(57) ABSTRACT

In one general aspect, an apparatus can include a semiconductor die, a molding material disposed around at least a portion of the semiconductor die, and a pair of leads electrically coupled to the semiconductor die and aligned along a first direction from the molding material. The molding material can define an elongated protrusion aligned along a second direction orthogonal to the first direction, and a notch disposed between the pair of leads.

### RELATED APPLICATION

This application claims priority to the and the benefit of U.S. Provisional Application No. 63/379,387 filed on Oct. 13, 2022, which is incorporated herein by reference in its entirety.

### TECHNICAL FIELD

This description relates to packaging of semiconductor die in high power device packages.

### BACKGROUND

Although discrete packages can be used in some applications, many discrete packages may not be effectively used in a variety of new applications and products.

### SUMMARY

In one general aspect, an apparatus can include a semiconductor die, a molding material disposed around at least a portion of the semiconductor die, and a pair of leads electrically coupled to the semiconductor die and aligned along a first direction from the molding material. The molding material can define an elongated protrusion aligned along a second direction orthogonal to the first direction, and a notch disposed between the pair of leads.

The details of one or more implementations are set forth in the accompanying drawings and the description below. Other features will be apparent from the description and drawings, and from the claims.

### BRIEF DESCRIPTION OF THE DRAWINGS

FIGS. 1A through 1C are diagrams that illustrate various views of a power module package.

FIG. 2 is a diagram that illustrates a heatsink coupled to the power module package shown in FIGS. 1A through 1C.

FIGS. 3A through 3C illustrate a variation of the power module package, shown in FIGS. 1A through 1C, where the notches have a different profile.

FIGS. 4A through 6D are diagrams that illustrate various implementations and views of power module packages.

FIGS. 7 through 12 illustrate variations of the power module packages described herein.

FIG. 13 illustrates a method of producing one or more of the power module packages described herein.

### DETAILED DESCRIPTION

This description relates to packaging of semiconductor die in high-power device packages. Modern high-power devices (e.g., power devices such as an insulated-gate bipolar transistor (IGBT), a fast recovery diode (FRD), converter, etc.) are fabricated in semiconductor die (e.g., silicon carbide (SiC) die). High-power device packages that can deliver, control, and/or switch high levels of power can be used in, for example, various types of vehicles including those powered by electricity (e.g., electric vehicles (EVs), hybrid electric vehicles (HEVs) and plug-in-electric vehicles (PHEV)).

This description is related specifically to power module packages for high-power devices (e.g., devices greater than 400V). The power module packages described herein can have a form factor that is configured to be used with various types of electronic circuits (e.g., interleaved power factor correction (PFC) circuit, half bridge rectifier circuit, full bridge rectifier circuit). In other words, the power module packages described herein can be a single platform (e.g., single platform with a standardized size) that can be used to package various types of integrated circuits fabricated within a die. The single platform can have a standardized set of leads (e.g., output leads, terminals, 32 pins) that can be utilized, as needed, for the various types of electric circuits packaged within the power module packages.

In some implementations, the power module packages described herein can be configured to be mirrored (e.g., symmetrical) about a longitudinal axis. In some implementations, the power module packages can include co-parallel terminals that are mirrored about the longitudinal axis. In some implementations, the power module packages can include co-parallel terminals. The power module packages described herein can be mirrored dual co-parallel terminals that enable the single (e.g., one) platform package for several electronics circuit packaged within the power module packages.

In some implementations, the power module packages described herein may not be configured to be mirrored about a longitudinal axis. In some implementations, the power module packages described herein may be asymmetrical about a longitudinal axis.

The power module packages described herein can be configured with a high creepage design that enables use in relatively high voltage applications. In some implementations, the high creepage design of the power module package can include one or more elongated protrusions (also can be referred to as a rib). The elongated protrusions can be separated from the main body of the power module package by at least one trench. In some implementations, the power module packages can be configured, using the elongated protrusion(s), with desirable lead-substrate (e.g., lead-to-substrate) backside isolation.

The power module package can be configured with desirable lead-lead (e.g., lead-to-lead) isolation and/or creepage distances. In some implementations, the power module packages described herein can be configured with one or more notches such that electrical isolation and/or creepage can be achieved between leads.

In some implementations, the power module packages can have various lead or pin options (e.g., dual in-line package (DIP), double DIP, surface mounted device (SMD)). In some implementations, the power module packages described herein can be formed using a transfer-molded process (also can be referred to as a transfer molding process).

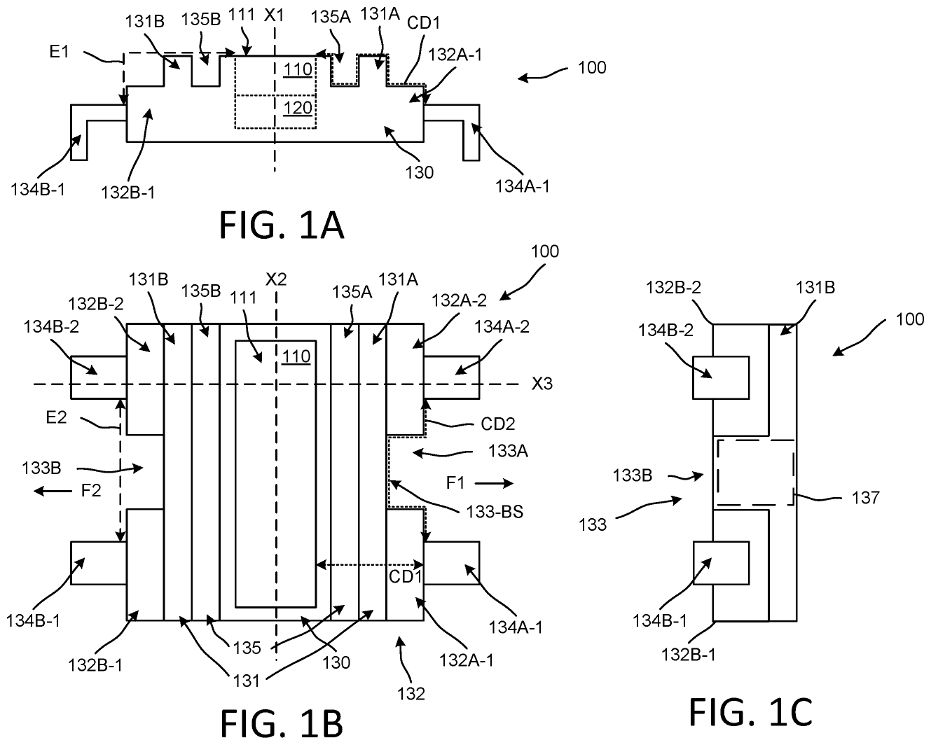

FIGS. 1A through 1C are diagrams that illustrate various views of a power module package 100. Specifically, FIG. 1A illustrates an end view, FIG. 1B illustrates a top view, and FIG. 1C illustrates a side view of the power module package 100.

As shown in FIGS. 1A through 1C, the power module package 100 includes a semiconductor die 120 (e.g., at least one semiconductor die) coupled to a substrate 110 and encapsulated within (e.g., entirely encapsulated within) a molding material 130.

In this implementation, the power module package 100 is symmetrical about an axis X1 (can be referred to as a vertical axis). In this implementation, the power module package 100 is symmetrical about an axis X2 (can be referred to as a longitudinal axis). In some implementations, a majority of, or all of, the features of the power module package 100 are symmetrical about the axis X1 and the axis X2. Accordingly, elements that are on one side of the power module package 100 (and are described as being on one side of the power module package 100), are replicated on the opposite side of the power module package 100 (and may not be described).

Although not shown, in some implementations, the power module package 100 may be asymmetrical about an axis X1 (can be referred to as a vertical axis). In some implementations, the power module package 100 is asymmetrical about the axis X2 (can be referred to as a longitudinal axis). For example, the power module package may be longer in a direction (e.g., a width direction) orthogonal to the axis X2 on one side of the axis X2 than on the other side of the axis X2. In some implementations, a majority of, or all of, the features of the power module package 100 are asymmetrical about the axis X1 and the axis X2. Accordingly, elements that are on one side of the power module package 100 (and are described as being on one side of the power module package 100), may not be replicated on the opposite side of the power module package 100.

Leads 134A-1, 134A-2, 134B-1, 134B-2 (collectively referred to as leads 134), can be coupled exposed through the molding material 130. One or more of the leads 134 can be referred to as terminal(s). For example, leads 134A-1 and 134A-2 can be referred to as a pair of leads. One or more of the leads 134 can be made of a metal material. The semiconductor die 120 can be coupled to one or more of the leads 134. The semiconductor die 120 can be configured to send and/or receive power, send and/or receive signals, etc. using one or more of the leads 134.

The substrate 110 can be a substrate with a metal layer. In some implementations, the substrate 110 can include one or more metal (e.g., copper metal or another type of metal) layers and/or one or more dielectric layers. In some implementations, the substrate 110 can be a direct bonded metal (DBM) substrate (e.g., a direct bonded copper (DBC) substrate). In some implementations, the substrate 110 can be DBM that includes a dielectric layer disposed between a pair of metal layers.

In some implementations, the substrate 110 can be exposed on a different side of the power module package 100 than shown in FIGS. 1A through 1C (or any of the implementations described herein). In some implementations, the substrate 110 can be exposed on one side of the power module package 100 and a different substrate or portion associated with a semiconductor die can be exposed on an opposite side of the power module package 100 shown in FIGS. 1A through 1C (or any of the implementations described herein).

As shown in FIGS. 1A through 1C, the substrate 110 can have a surface 111 (e.g., a top surface, a conductive surface) exposed through (or outside of) the molding material 130 (e.g., a surface exposed through a top surface of the substrate 110). In some implementations, the substrate 110 can have a metal layer surface exposed through the molding material 130. In other words, the surface 111 can be a metal layer surface. In some implementations, the substrate 110 can have a conductive surface exposed through the molding material 130. In some implementations, a heatsink (not shown in this embodiment), for example, can be coupled to the substrate 110 (e.g., coupled to a metal layer surface of the substrate 110 exposed through the molding material 130).

As shown in FIGS. 1A through 1C, the power module package 100 includes elongated protrusions 131A and 131B. As shown in FIG. 1B, the elongated protrusions 131A, 131B extend along (e.g., are aligned parallel to) the axis X2. The elongated protrusions 131A and 131B are defined by (e.g., separated from a main portion of the power module package 100) trenches 135A and 135B, respectively. As shown in FIG. 1B, the trenches 135A, 135B extend along (e.g., are aligned parallel to) the axis X2. The elongated protrusions 131A, 131B can collectively be referred to as elongated protrusions 131. The trenches 135A, 135B can collectively be referred to as trenches 135.

As shown in FIG. 1A, the protrusion 131A, for example, can be configured to define a lead-substrate creepage distance CD1 from the lead 134A-1 to the surface 111 of the substrate 110 along the surface of the molding material 130. The lead-substrate creepage distance CD1 is increased by the protrusion 131A (and trench 135A) as shown in FIG. 1A. In other words, the protrusion 131A and the trench 135A collectively define at least a portion of the lead-substrate creedpage distance CD1. Without the protrusion 131A and the profile of the protrusion 131A, the lead-substrate creepage distance CD1 would be much shorter. The lead-substrate creepage distance CD1 is also shown in FIG. 1B from a top view. An example of what the lead-substrate creepage distance would look like without one or more of the protrusions is shown as line E1.

The relatively large lead-substrate creepage distance CD1 can allow for a higher voltage of the semiconductor die 120 (or other device) within the power module package 100 than would otherwise be possible. In other words, without the elongated protrusions 131 power module package 100 would not be able to operate at as high of a voltage.

As shown in FIG. 1A, the elongated protrusions 131A, 131B of the power module package 100 each have a rectangular or square cross-sectional profile. In some implementations, the cross-sectional profile of one or more of the elongated protrusions 131A, 131B of the power module package 100 can be different than shown. In some implementations, one or more of the corners of the cross-sectional profile of one or more of the elongated protrusions 131A, 131B of the power module package 100 can be curved. In some implementations, one or more of sidewalls of the cross-sectional profile of one or more of the elongated protrusions 131A, 131B of the power module package 100 can be sloped and/or curved. As shown in FIG. 1A the elongated protrusions 131A, 131B have a top surface that is within a same plane as the substrate 110 and/or the molding material 130 around the substrate 110.

As shown in FIG. 1A, the trenches 135A, 135B of the power module package 100 each have a rectangular or square cross-sectional profile. In some implementations, the cross-sectional profile of one or more of the trenches 135A, 135B of the power module package 100 can be different than shown. In some implementations, one or more of the corners of the cross-sectional profile of one or more of the trenches 135A, 135B of the power module package 100 can be curved. In some implementations, one or more of sidewalls of the cross-sectional profile of one or more of the trenches 135A, 135B of the power module package 100 can be sloped and/or curved.

Although illustrated with a single elongated protrusion and trench on each of the power module package 100, in some implementations, the power module package 100 can include more than one elongated protrusion and trench along one or more sides of the power module package 100. In some implementations, the power module package 100 can exclude an elongated protrusion and a trench from at least one side of the power module package 100.

As shown in FIGS. 1A through 1C, the power module package 100 includes notches 133A and 133B. The notch 133A is defined between extensions 132A-1 and 132A-2. The notch 133A is defined between extensions 132A-1 and 132A-2. Also, the notch 133B is defined between extensions 132B-1 and 132B-2. The extensions 132A-1, 132A-2, 132B-1, and 132B-2 can collectively be referred to as extensions 132. The notches 133A, 133B can collectively be referred to as notches 133.

As shown in FIG. 1B, the notches 133 face away from (along directions F1 and F2) the axis X2. In other words, the notches 133 define an opening that faces away from the axis X2. In other words, the deepest portion, or bottom surface (e.g., bottom surface 133-BS), of the notches 133 face outward away from the axis X2. A U-shape (as shown from the plan view shown in FIG. 1B) of the notches 133 is aligned within a plane (e.g., plane P1 shown in FIG. 1A) of the power module package 100.

As shown in FIG. 1B, the notch 133A, for example, can be configured to define a lead-lead creepage distance CD2 from between the lead 134A-1 and the lead 134A-2 along the surface of the molding material 130. The lead-lead creepage distance CD2 is increased by the notch 133A as shown in FIG. 1B. Without the notch 133A and the profile of the notch 133A, the lead-lead creepage distance CD2 would be much shorter. An example of what the lead-lead creepage distance would look like without one or more of notches is shown as line E2.

The relatively large lead-lead creepage distance CD2 can allow for a higher voltage of the semiconductor die 120 (or other device) within the power module package 100 than would otherwise be possible. In other words, without the notches 133 power module package 100 would not be able to operate at as high of a voltage. As a specific example, the lead 134A-1 can be a source lead of a transistor and the lead 134A-2 can be a drain lead of the transistor. The lead-lead creepage distance CD2 can allow for a greater drain to source voltage than would be possible without the lead-lead creepage distance CD2 between the leads 134A-1, 134A-2.

The notches 133A and 133B of the power module package 100 each have a rectangular or square top-view profile when viewed from above, as shown in FIG. 1B. In some implementations, the top-view profile of one or more of the notches 133A, 133B of the power module package 100 can be different than shown. In some implementations, one or more of the corners of the top-view profile of one or more of the notches 133A, 133B of the power module package 100 can be curved. In some implementations, one or more of sidewalls of the top-view profile of one or more of the notches 133A, 133B of the power module package 100 can be sloped and/or curved.

The extensions 132 of the power module package 100 each have a rectangular or square top-view profile when viewed from above, as shown in FIG. 1B. In some implementations, the top-view profile of one or more of the extensions 132 of the power module package 100 can be different than shown. In some implementations, one or more of the corners of the top-view profile of one or more of the extensions 132 of the power module package 100 can be curved. In some implementations, one or more of sidewalls of the top-view profile of one or more of the extensions 132 of the power module package 100 can be sloped and/or curved.

As shown in FIG. 1B, the elongated protrusions 131 are aligned along (e.g., extend parallel to) the axis X2 (which can be a longitudinal axis). The axis X2 can be a longitudinal axis of the power module package 100. The axis X2 can be aligned along a direction orthogonal to axis X3. The leads 134 extend outward from the molding material 130 along the axis X3. The leads 134 are aligned along the axis X3. Accordingly, the elongated protrusions 131 are aligned along a direction orthogonal to the direction along which the leads 134 are aligned.

As shown in FIG. 1B, the elongated protrusion 131A has an outside surface aligned along an inner surface of the notch 133A. An example of such a surface is shown as the plane or surface 137 in FIG. 1C (surface 137 along elongated protrusion 131B and notch 133B).

In some implementations, the number of leads 134 can be standardized across the various electronic circuits that are packaged within the power module packages. For example, the number of leads 134 can be 32 leads regardless of the electronic circuit or semiconductor die that is packaged therein. In some implementations, some of the leads 134 may not be active leads. In some implementations, the number of leads 134 can be greater than 32 leads or less than 32 leads.

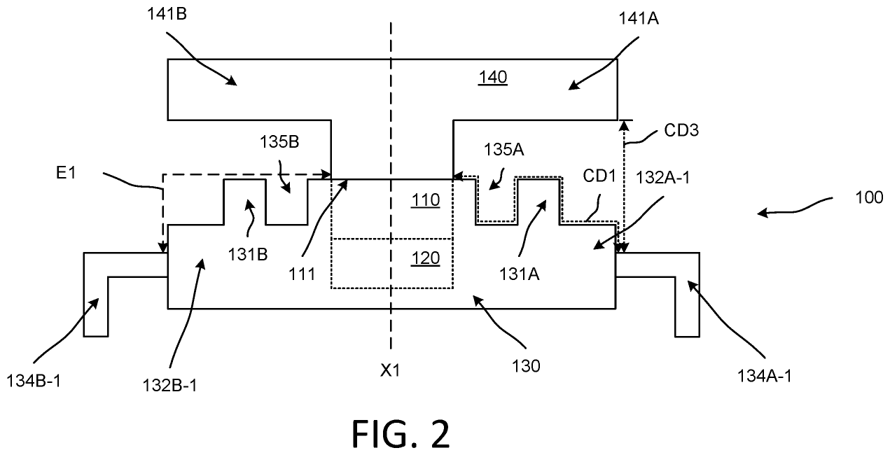

FIG. 2 is a diagram that illustrates a heatsink 140 coupled to the power module package 100 shown in FIGS. 1A through 1C. As shown in FIG. 2, the heatsink 140 has a T-shaped profile (when viewed from the side or in cross-section). In this implementation, the heatsink 140 is coupled to the surface 111 of the substrate 110. In this implementation, the heatsink 140 has cantilevered portions 141A, 141B that are disposed over the elongated protrusions 131.

As shown in FIG. 2, the cantilevered portions 141A, 141B is greater than or equal to the lead-substrate creepage distance CD1 are separated from the leads 134 by a distance that is greater than or equal to the lead-substrate creepage distance. For example, a distance CD3 between lead 134A-1 and the cantilevered portion 141A of the heatsink 140 is greater than or equal to the lead-substrate creepage distance CD1.

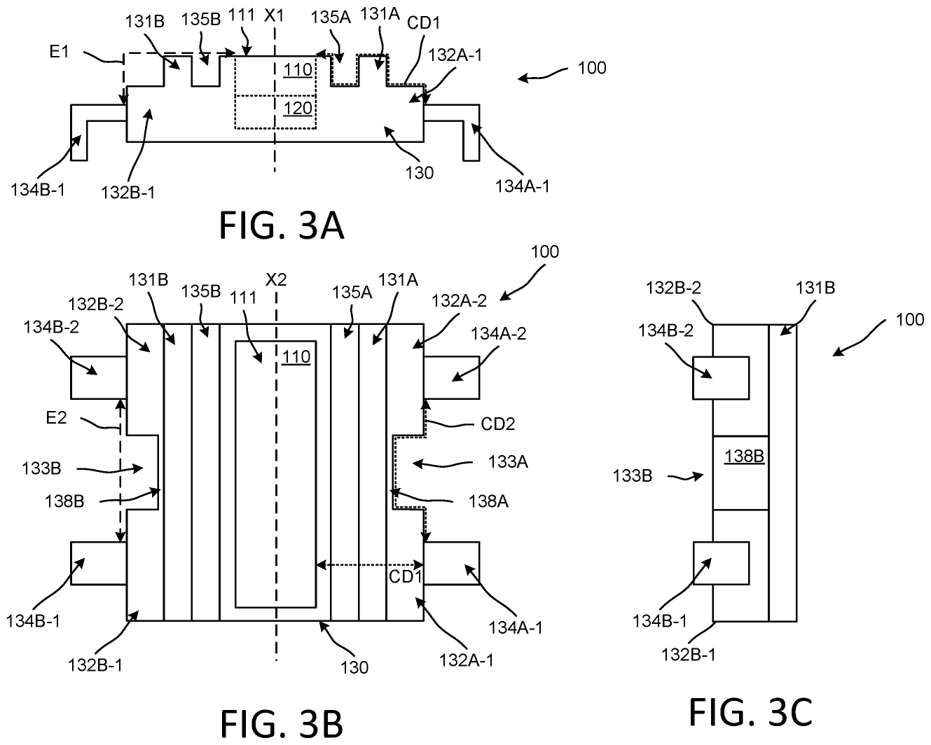

FIGS. 3A through 3C illustrate a variation of the power module package 100 (shown in FIGS. 1A through 1C) where the notches 133 have a different profile. As shown in FIGS. 3B and 3C, the elongated protrusion 131A has an outside surface that is not aligned along an inner surface of the notch 133A. Specifically, a bridge portion 138A is disposed between extensions 132A-1 and 132A-2, and a bridge portion 138B is disposed between extensions 132B-1 and 132B-2.

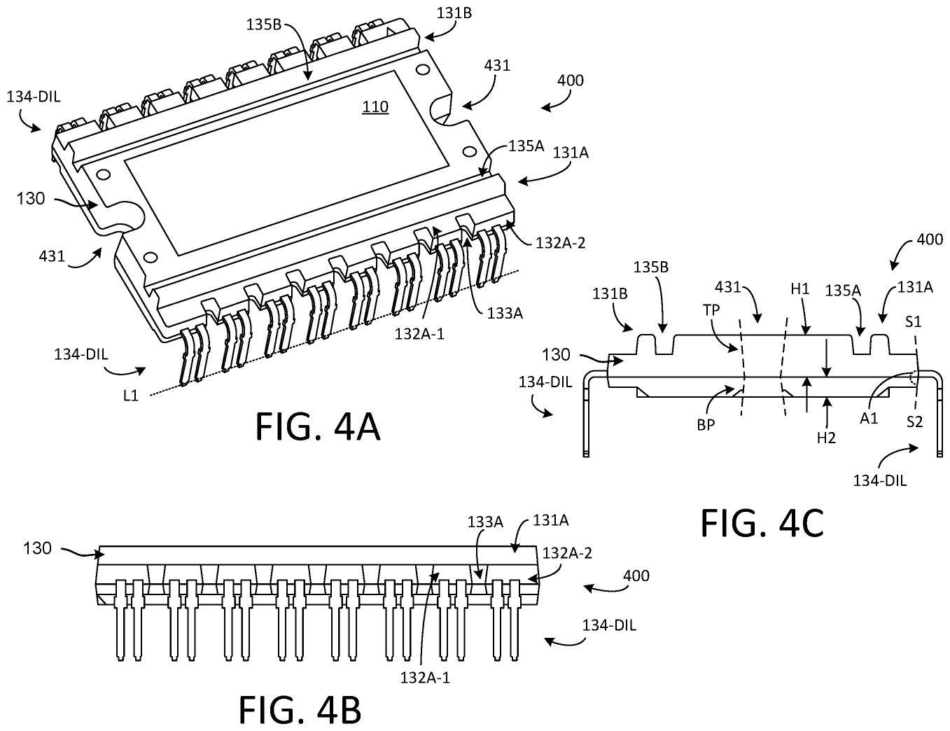

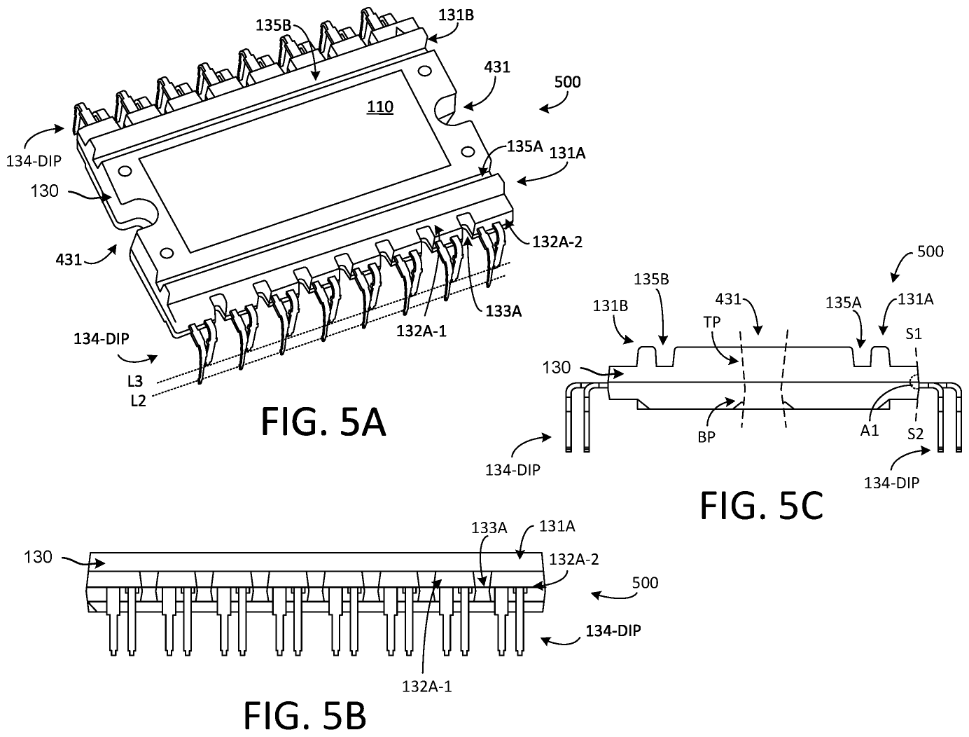

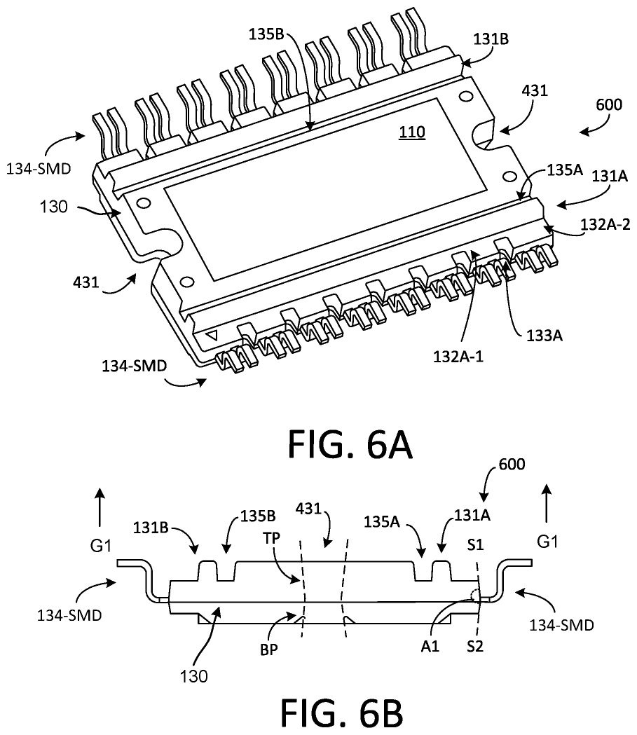

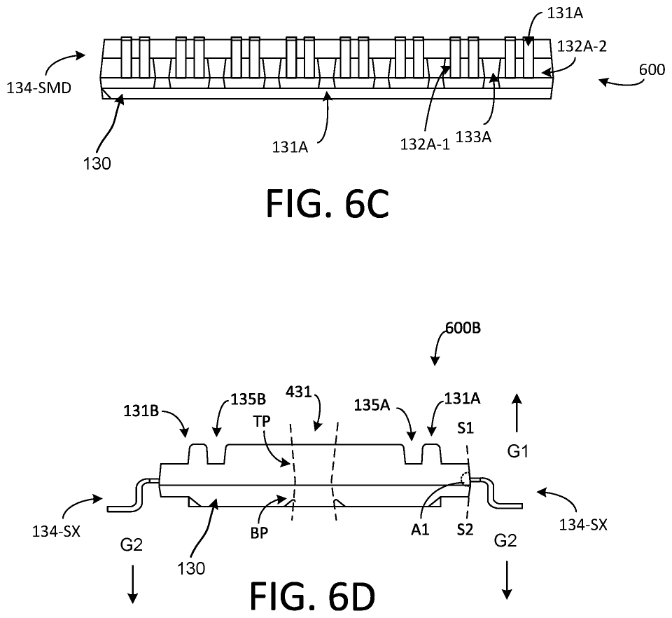

As described above, in some implementations, the power module packages 100 can have various lead or pin variations. These variations are shown and described in at least FIGS. 4A through 6C. Specifically, FIGS. 4A through 4C (perspective, side, and end views, respectively) illustrate a power module package 400 that is a dual in-line package (DIP). FIGS. 5A through 5C (perspective, side, and end views, respectively) illustrate a power module package 500 that is a double DIP. FIGS. 6A through 6C (perspective, side, and end views, respectively) illustrate a power module package 600 that is a surface mounted device (SMD). These implementations in FIGS. 4A through 6C have many of the same elements as in FIGS. 1 through 3C above (and are labeled accordingly).

The power module package 400 shown in FIG. 4A includes dual in-line leads 134-DIL (e.g., two leads per extension such as extension 132A-2) that are, for example, aligned along line L1. As shown in FIG. 4A, the power module package 400 includes end recesses 431 in which one or more objects (e.g., members) can be placed. In some implementations, one or more of these end recesses 431 can be recesses in which one or more, for example, bolts, coupling members, and/or so forth can be disposed. In some implementations, a heatsink (not shown) coupled to a top of the power module package 400 can be coupled to, for example, a circuit board (e.g., a printed circuit board) below the power module package 400 using a bolt that has at least a portion disposed in at least one of the end recesses 431. In such implementations, the power module package 400 can be disposed between the heatsink and the circuit board.

As shown in FIG. 4C, the power module package 400 can have sidewalls with sloped surfaces. For example, an outside surface of the power module package 400 can have a first sloped surface S1 and a second sloped surface S2. Accordingly, the outside surface of the power module package 400 can have surfaces that define an obtuse angle A1. The outside surface of the power module package 400 can have pointed shape.

As shown in FIG. 4C, the sidewalls of the end recesses 431 can be sloped as well. Accordingly, a top portion TP and a bottom portion BP of the end recess 431 can each taper inward toward a middle portion of the end recess 431. The top portion TP can have an opening that is a different size (e.g., different width or diameter) than an opening of the bottom portion BP of the end recess 431.

As shown in FIG. 4C, the sidewalls of the elongated protrusions 131A, 131B are sloped (or tapered towards their respective top surfaces). In this implementation, the top edges of the elongated protrusions 131A, 131B are curved.

As shown in FIG. 4C, the sidewalls of the trenches 135A, 135B are sloped (or tapered towards their respective bottom surfaces). In this implementation, the bottom edges of the trenches 135A, 135B are curved.

As shown in FIG. 4C, a height H1 of a top portion of the power module package 400 is greater than a height H2 of a bottom portion of the power module package 400. The top portion of the power module package 400 and the bottom portion of the power module package 400 are separated by (e.g., defined by) the inflection at (e.g., defined by) the angle A1 (between first sloped surface S1 and the second sloped surface S2). The top portion (with the greater height H1) is a side of the power module package 400 with the substrate 110, which is exposed.

As shown in FIGS. 5A through 5C, the power module package 500 has many of the features discussed in connection with FIGS. 4A and 4C. The power module package 500 shown in FIG. 5A includes double DIP leads 134-DIP that are, for example, aligned along lines L2 and L3.

As shown in FIGS. 6A through 6C, the power module package 600 has many of the features discussed in connection with FIGS. 4A and 5C. The power module package 600 shown in FIG. 6A includes leads 134-SMD that are facing toward a same direction (along direction G1) as the surface of the substrate 110 and is a surface mounted device (SMD).

FIG. 6D illustrates a power module package 600B that is a variation of the power module package 600 shown in FIGS. 6A through 6C where leads 134-SX are facing in an opposite direction as leads 134-SMD shown in FIGS. 6A through 6C. Specifically, the leads 134-SX are facing in a direction G2, which is opposite direction G1 (shown in FIG. 6B). In such implementations, the substrate 110 (not shown in FIG. 6D) can be exposed outside of the molding material 130 facing toward the direction G1 or direction G2.

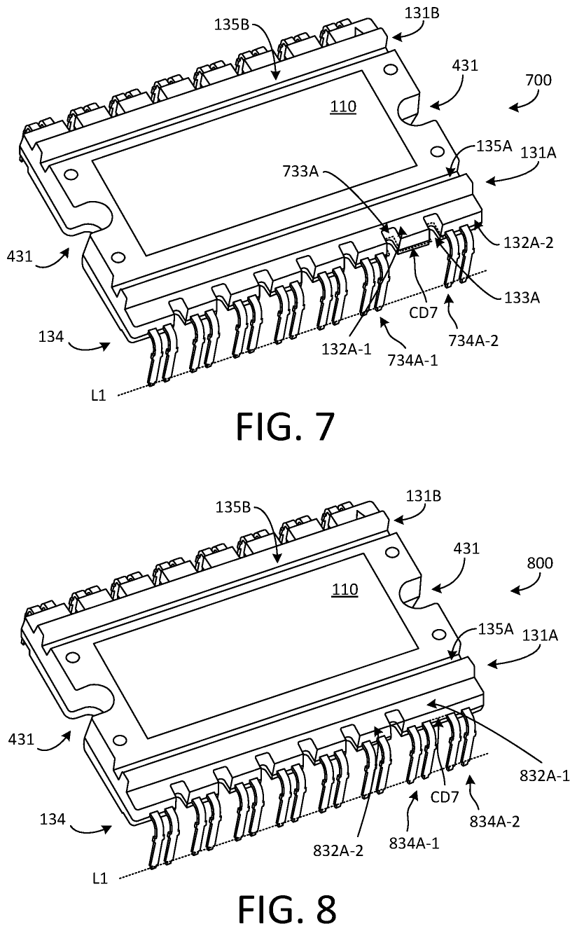

FIG. 7 illustrates a variation of the power module packages described herein where an extension excludes a lead. Specifically, FIG. 7 illustrates a power module package 700 variation of power module package 400 shown in FIG. 4A with leads excluded from extension 132A-1. In this implementation, a creepage distance CP7 is between leads 734A-1 and 734A-2 and includes extension 132A-1. In this implementation, the creepage distance CP7 has been increased over the implementation shown in FIG. 4A. In this implementation, the creepage distance CP7 includes the extension 132A-1. In this implementation, the creepage distance CP7 includes notch 133A and notch 733A.

Although only one extension is illustrated with no leads in the variation in FIG. 7, in some implementations, more than one extension and/or a different extension than shown in FIG. 7 can have leads excluded.

Although this variation in FIG. 7 is illustrated with respect to the power module package 400 (DIP) shown in FIG. 4A, the concepts described in connection with FIG. 7 can be applied to any of the implementations described herein including the power module package 500 (double DIP) of FIGS. 5A through 5C and/or the power module package 600 (SMD) of FIGS. 6A through 6C.

FIG. 8 illustrates a variation of the power module packages described herein where notches are excluded between some leads. Specifically, FIG. 8 illustrates a power module package 800 variation of power module package 400 shown in FIG. 4A with at least notch 133A excluded from extension 132A-1 to define extension 832A-1 with two pairs of leads 834A-1 and 834A-2. In this implementation, a creepage distance CP8 is between leads 834A-1 and 834A-2. In this implementation, the creepage distance CP8 has been decreased over the implementation shown in FIG. 4A. As shown in FIG. 8, the extension 832A-1 has a width that is greater than a width of the extension 832A-2.

Although only one notch is excluded in the variation in FIG. 8, in some implementations, more than one notch and/or a different notch than shown in FIG. 8 can be excluded.

Although this variation in FIG. 8 is illustrated with respect to the power module package 400 (DIP) shown in FIG. 4A, the concepts described in connection with FIG. 8 can be applied to any of the implementations described herein including the power module package 500 (double DIP) of FIGS. 5A through 5C and/or the power module package 600 (SMD) of FIGS. 6A through 6C.

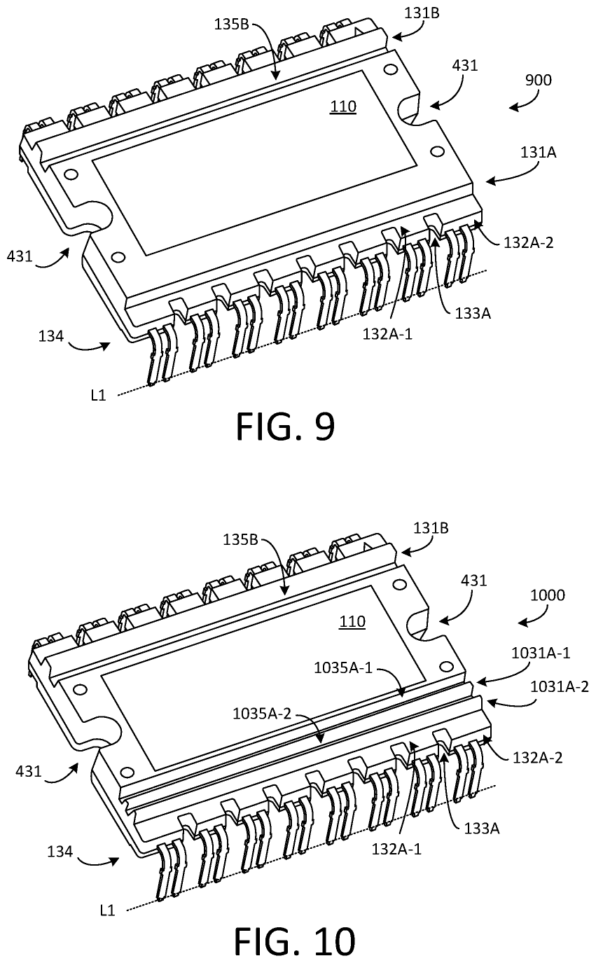

FIG. 9 illustrates a variation of the power module packages described herein where at least one trench is excluded. Specifically, FIG. 9 illustrates a power module package 900 variation of power module package 400 shown in FIG. 4A with trench 135A excluded from the power module package 400. Accordingly, only trench 135B is included in the power module package 900.

Although only one trench is excluded in the variation in FIG. 8, in some implementations, more than one trench and/or a different trench than shown in FIG. 8 can be excluded.

Although this variation in FIG. 9 is illustrated with respect to the power module package 400 (DIP) shown in FIG. 4A, the concepts described in connection with FIG. 9 can be applied to any of the implementations described herein including the power module package 500 (double DIP) of FIGS. 5A through 5C and/or the power module package 600 (SMD) of FIGS. 6A through 6C.

FIG. 10 illustrates a variation of the power module packages described herein with multiple trenches and multiple elongated protrusions. Specifically, FIG. 10 illustrates a power module package 1000 variation of power module package 400 shown in FIG. 4A with trenches 1035A-1 and 1035A-2 on one side of the substrate 110. FIG. 10 illustrates the power module package 1000 with elongated protrusions 1031A-1 and 1031A-2 on one side of the substrate 110.

Although only one side of the power module package 1000 in the variation of FIG. 10 includes multiple trenches, in some implementations, more than two trenches (and more than two elongated protrusions) can be included in the power module package 1000. In some implementations, both sides of the power module package 1000 can include more than one trench (and more than one elongated protrusion).

Although this variation in FIG. 10 is illustrated with respect to the power module package 400 (DIP) shown in FIG. 4A, the concepts described in connection with FIG. 10 can be applied to any of the implementations described herein including the power module package 500 (double DIP) of FIGS. 5A through 5C and/or the power module package 600 (SMD) of FIGS. 6A through 6C.

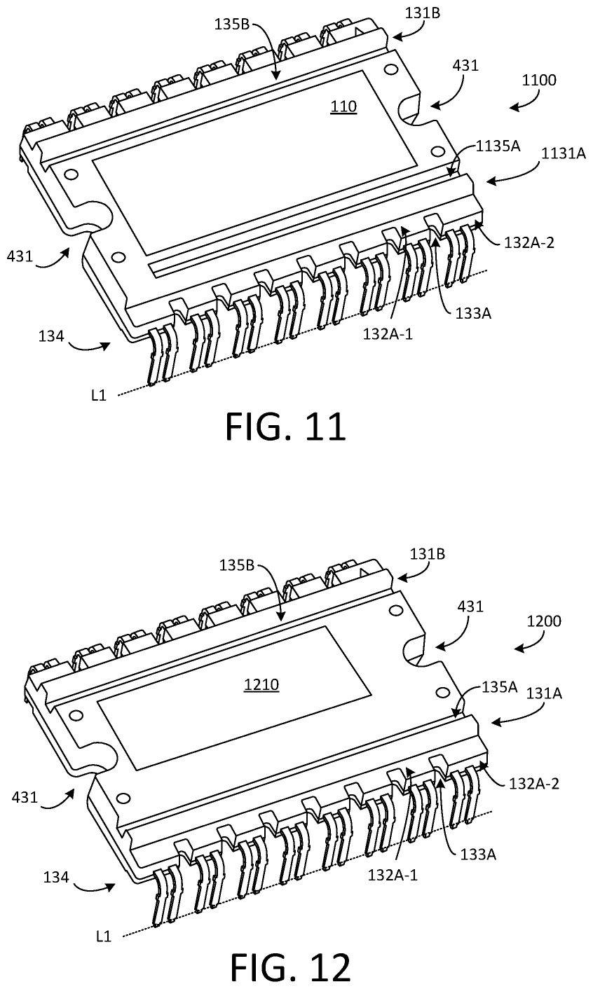

FIG. 11 illustrates a variation of the power module packages described herein with multiple trenches and multiple elongated protrusions. Specifically, FIG. 11 illustrates a power module package 1100 variation of power module package 400 shown in FIG. 4A with a trench 1135A (and corresponding elongated protrusion 1131A) shorter than an entire length (e.g., less than 100%, less than 75%, less than 50%) of the power module package 1100. In this implementation, only one side of the trench 1135A (e.g., only one longitudinal end) does not extend to an end of the power module package 1100. In some implementations, both ends of the trench 1135A do not extend to an end of the power module package 1100. In some implementations, more than one trench may have one or more ends that do not extend to an end of the power module package 1100. Although this variation in FIG. 11 is illustrated with respect to the power module package 400 (DIP) shown in FIG. 4A, the concepts described in connection with FIG. 11 can be applied to any of the implementations described herein including the power module package 500 (double DIP) of FIGS. 5A through 5C and/or the power module package 600 (SMD) of FIGS. 6A through 6C.

FIG. 12 illustrates a variation of the power module packages described herein with the substrate asymmetrical disposed. Specifically, FIG. 12 illustrates a power module package 1200 variation of power module package 400 shown in FIG. 4A with a substrate 1210 that is not symmetrically disposed within the power module package 1200.

Although this variation in FIG. 12 is illustrated with respect to the power module package 400 (DIP) shown in FIG. 4A, the concepts described in connection with FIG. 12 can be applied to any of the implementations described herein including the power module package 500 (double DIP) of FIGS. 5A through 5C and/or the power module package 600 (SMD) of FIGS. 6A through 6C.

The variations illustrated in FIGS. 7 through 12 can be combined in any combination except for mutually exclusive combinations. For example, the features of the power module package 700 shown in FIG. 7 can be combined with any of the features of the power module packages 800 through 1200 shown in FIGS. 8 through 12. As another example, the features of the power module package 800 shown in FIG. 8 can be combined with any of the features of the power module packages 700, and 900 through 1200 shown in FIGS. 7 and 9 through 12. As another example, the features of the power module package 900 shown in FIG. 9 can be combined with any of the features of the power module packages 700, 800, and 1000 through 1200 shown in FIGS. 7, 8, and 10 through 12.

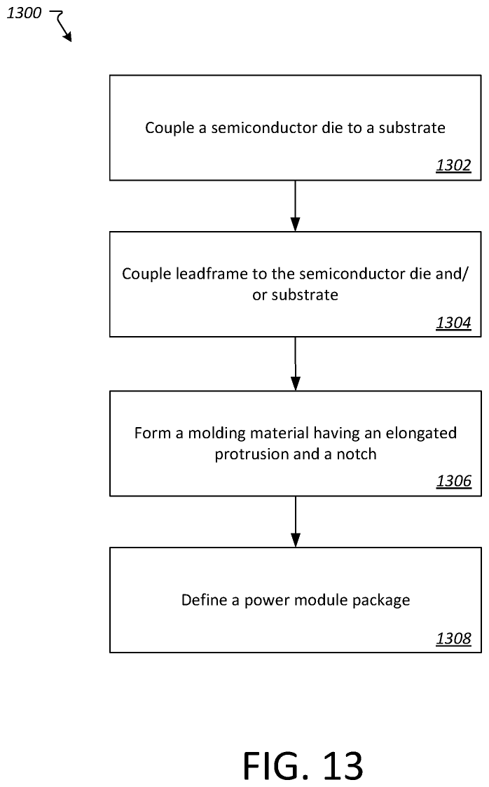

FIG. 13 illustrates a method 1300 of producing one or more of the power module packages described herein. The method in FIG. 13 can be used to form any of the power module packages (e.g., the power module packages shown in FIGS. 1A through 12) described herein.

As shown in FIG. 13, the method 1 can include coupling a semiconductor die to a substrate (block 1302). The semiconductor die can be the semiconductor die 120 and the substrate can be the substrate 110 shown in, for example, FIGS. 1A through 1C. In some implementations, solder is printed on the substrate so that the semiconductor die may be coupled to the substrate. The coupling can include die mounting on the printed solder of the substrate. In some implementations, a metal layer on the substrate can be patterned. In some implementations, the metal layer on the substrate can be patterned (e.g., patterned using an etch) before solder is printed on the substrate.

In some implementations, a leadframe can be coupled to the semiconductor die and/or the substrate (block 1304). At least a portion of the leadframe can be coupled to the semiconductor die and/or the substrate directly (e.g., directly via a solder) and/or via a wirebond. In some implementations, at least a portion of the leadframe can be coupled to the semiconductor die and/or the substrate via a reflow process. In some implementations, portions of the leadframe can define one or more leads (e.g., leads 134 shown in FIGS. 1A through 1C). In some implementations, portions of the leadframe can be cut to define one or more leads.

As shown in FIG. 13, a molding material (e.g., molding) having an elongated protrusion and a notch is formed (block 1306). The elongated protrusion can be at least one of the elongated protrusions shown in FIGS. 1A through 1C. The notch can be at least one of the notches 133 shown in FIGS. 1A through 1C. In some implementations, the elongated protrusion can be aligned a longitudinal axis. In some implementations, the notch can face in a direction away from the longitudinal axis In some implementations, the molding material can be formed using, for example, a transfer pressure molding process (e.g., transfer molding process). In some implementations, the elongated protrusion can be aligned along a direction orthogonal to a direction of one or more leads extending from a side of the molding material. In some implementations, the notch can be disposed between the pair of leads. In some implementations, the notch can be disposed between the pair of leads. In some implementations, the notch can be defined between a pair of extensions (e.g., extensions 132 shown in FIGS. 1A through 1C). Any of the features described above (e.g., end recesses, trenches, sloped walls, and/or so forth) can be formed using, for example, the transfer pressure molding process.

In some implementations, the molding material can be formed around the semiconductor die, at least a portion of the substrate, and/or at least a portion of the leadframe. In some implementations, the semiconductor die can be entirely encapsulated within the molding material. In some implementations, one or more wirebonds coupled to the semiconductor die can be entirely encapsulated within the molding material. A surface (e.g., a top surface) of the substrate may be exposed through the molding as shown in, for example, FIGS. 1A through 1C.

In some implementations, the power module package can be defined (block 1308). The power module package can be defined by trimming and/or forming. For example, as mentioned above, one or more portions of the leadframe can be cut (e.g., trimmed) to define one or more leads. In some implementations, one or more portions of the leads, which are cut from the leadframe, can be formed (e.g., bent) to define one or more power module package configurations.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Implementations of the various techniques described herein may be implemented in (e.g., included in) digital electronic circuitry, or in computer hardware, firmware, software, or in combinations of them. Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An apparatus, comprising:
a semiconductor die;
a molding material disposed around at least a portion of the semiconductor die; and
a pair of leads electrically coupled to the semiconductor die and aligned along a first direction from the molding material,
the molding material defining:
an elongated protrusion aligned along a second direction orthogonal to the first direction, and
a notch disposed between the pair of leads.

2. The apparatus of claim 1, further comprising:
a substrate coupled to the semiconductor die and having a conductive surface exposed outside of the molding material.

3. The apparatus of claim 2, wherein the molding material defines a trench disposed between the elongated protrusion and the conductive surface.

4. The apparatus of claim 3, wherein the trench is aligned along the second direction.

5. The apparatus of claim 1, wherein the notch is disposed between a pair of extensions made from the molding material.

6. The apparatus of claim 1, wherein the elongated protrusion and a trench collectively define at least a portion of a lead-substrate creepage distance.

7. The apparatus of claim 1, wherein the notch has a surface that defines at least a portion of a lead-lead creepage distance.

8. The apparatus of claim 1, wherein at least one of the pair of leads is electrically coupled to the semiconductor die via a wirebond.

9. A method, comprising:
coupling a semiconductor die to a substrate;
coupling a leadframe to at least one of the semiconductor die or the substrate; and
forming a molding material having an elongated protrusion and a notch, the elongated protrusion being aligned along a longitudinal axis, and the notch facing in a direction away from the longitudinal axis.

10. The method of claim 9, wherein the semiconductor die is coupled to the substrate via a printed solder.

11. The method of claim 9, wherein the leadframe is coupled to the semiconductor die via a wirebond.

12. The method of claim 9, wherein the molding material is formed using a transfer molding process.

13. The method of claim 9, further comprising:
trimming the leadframe to define a plurality of leads extending from the molding material along a first direction,
the elongated protrusion being aligned along a second direction orthogonal to the first direction, and
the notch being disposed between a pair of the plurality of leads.

14. An apparatus, comprising:
a semiconductor die;
a molding material disposed around at least a portion of the semiconductor die;
a first lead extending along a first direction away from the molding material; and
a second lead extending along a first direction away from the molding material,
the molding material defining:
a trench aligned along a second direction orthogonal to the first direction, and
a notch disposed between the first lead and the second lead.

15. The apparatus of claim 14, further comprising:
a substrate coupled to the semiconductor die and having a conductive surface exposed outside of the molding material.

16. The apparatus of claim 14, wherein the molding material defines an elongated protrusion disposed between the trench and notch.

17. The apparatus of claim 16, wherein the trench and the elongated protrusion collectively define at least a portion of a lead-substrate creepage distance.

18. The apparatus of claim 14, wherein the trench is aligned along the second direction.

19. The apparatus of claim 14, wherein the notch is disposed between a pair of extensions made from the molding material, the notch faces in a direction away from the second direction.

20. The apparatus of claim 14, wherein the notch has a surface that defines at least a portion of a lead-lead creepage distance.
